(19) United States
(12) Patent Application Publication
(10) Pub. No.: US 2023/0029724 A1
(43) Pub. Date: Feb. 2, 2023

(54) SYSTEM AND METHOD FOR MONITORING PRECURSOR DELIVERY TO A PROCESS CHAMBER

(71) Applicant: ASM IP Holding B.V., Almere (NL)

(72) Inventor: William George Petro, Scottsdale, AZ (US)

(21) Appl. No.: 17/871,048

(22) Filed: Jul. 22, 2022

Related U.S. Application Data
(60) Provisional application No. 63/203,623, filed on Jul. 27, 2021.

(51) Int. Cl. C23C 16/52; C23C 16/455

(52) U.S. Cl. CPC C23C 16/52; C23C 16/45544

(57) ABSTRACT

A semiconductor processing method for monitor the dose of a precursor from a solid or liquid source that utilize a caner gas and a semiconductor processing system are disclosed. A pressure or mass-flow controller is used to monitor the carrier as flow into the vessel and mass-flow meter is used to measure that total flow out of the vessel. Based on the difference between these two flows, the precursor flow is obtained and a dose of a solid or liquid precursor to a process chamber and a remaining amount in a source vessel is calculated.

### CROSS-REFERENCE TO RELATED APPLICATIONS

This application claims priority to U.S. Provisional Patent Application Ser. No. 63/203,623 filed Jul. 27, 2021 and titled SYSTEM AND METHOD FOR MONITORING PRECURSOR DELIVERY TO A PROCESS CHAMBER, the disclosure of which is hereby incorporated by reference in its entirety.

### FIELD

The field generally relates to a system and method for monitoring a dose of a precursor from a solid or liquid source to a process chamber. Various embodiments also relate to a method for in-situ direct monitoring of the precursor from a solid source to determine if a level of the solid chemical precursor is low in a source vessel.

### BACKGROUND

During semiconductor processing, various reactant vapors are fed into a process chamber (also referred to herein as a reaction chamber). In some applications, the reactant vapors are stored in gaseous form in a reactant source vessel. In such applications, the reactant vapors are often gaseous at ambient pressures and temperatures. However, in some cases, the vapors of source chemicals that are liquid or solid at ambient pressure and temperature are used. These substances may be heated to produce sufficient amounts of vapor for the reaction process, such as vapor deposition. Chemical Vapor Deposition (CVD) used in the semiconductor industry may call for continuous streams of reactant vapor, and Atomic Layer Deposition (ALD) may call for continuous streams or pulsed supply, depending on the configuration. In both cases it can be important to know with a relatively high degree accuracy the amount of reactant supplied per unit time or per pulse in order to control the doses and effect on the process.

### SUMMARY

In view of the above mentioned situation, one object of one or more aspects of the disclosed embodiments is to provide a method for monitoring a dose of a solid or liquid precursor to a process chamber.

In one embodiment, the method may include measuring an input flow of carrier gas flowing into a source vessel in which a solid or liquid precursor is disposed. The method may also include vaporizing the precursor and entraining the vaporized precursor with the carrier gas and measuring an output flow of the entrained carrier gas and vaporized precursor from the source vessel. The method may further include calculating a volume flow rate of the vaporized precursor based on the measured input flow and the measured output flow.

Another object of one or more aspects of the disclosed embodiments is to provide a method for calculating a remaining amount of precursor in a source vessel.

In one embodiment, the method may include measuring an input flow of carrier gas flowing into a source vessel in which a solid or liquid precursor is disposed. The method may also include vaporizing the precursor and entraining the vaporized precursor with the carrier gas and measuring an output flow of the entrained carrier gas and vaporized precursor from the source vessel. The method may further include calculating a remaining amount of the precursor in the vessel based on the measured input flow and the measured output flow.

Yet another object of one or more aspects of the disclosed embodiments is to provide a semiconductor processing system. In one embodiment, the system may include a source vessel configured to contain a solid or liquid precursor. The system may also include a first flow measurement device, which is configured to measure a flow of a carrier gas to the source vessel, in fluid communication with an inlet of the source vessel and a second flow measurement device, which is configured to measure an output flow of the entrained carrier gas and vaporized precursor from the source vessel, in fluid communication with an outlet of the source vessel. The system may further include a process chamber, which is configured to receive one or more substrates, in fluid communication with the second flow measurement device and a controller configured to calculate a volume flow rate of the vaporized precursor based on the measured input flow and the measured output flow.

### BRIEF DESCRIPTION OF THE DRAWINGS

The foregoing and other objectives and advantages will appear from the description to follow. In the description reference is made to the accompanying drawing, which forms a part hereof, and in which is shown by way of illustration specific embodiments in which the disclosed embodiments may be practiced. These embodiments will be described in sufficient detail to enable those skilled in the art to practice the disclosed embodiments, and it is to be understood that other embodiment may be utilized and the structural changes may be made without departing from the scope of the disclosed embodiments. The accompanying drawing, therefore, is submitted merely as showing the preferred exemplification of the disclosed embodiments. Accordingly, the following detail description is not to be taken in a limiting sense, and the scope of the present disclosed embodiments is best defined by the appended claims.

FIG. 1 is a flowchart illustrating a semiconductor processing method, according to various embodiments.

FIG. 2 is a schematic diagram of semiconductor processing device, according to one embodiment.

### DETAILED DESCRIPTION

For some solid and liquid substances, the vapor pressure at room temperature may be low such that the solid or liquid precursors are heated to produce a sufficient amount of reactant vapor. Once vaporized, it is important that the vapor phase reactant is kept in vapor form through the processing system so as to prevent undesirable condensation in reaction chamber, and in the valves, filters, conduits and other components associated with delivering the vapor phase reactants to the reaction chamber. Vapor phase reactant from such solid or liquid substances can also be useful for other types of chemical reactions for the semiconductor industry (e.g., etching, doping, etc.) and for a variety of other industries, but are of particular concern for metal and semiconductor precursors employed, e.g., in CVD or ALD.

ALD is a method for growing highly uniform thin films onto a substrate. In a time-divided ALD reactor, the substrate is placed into reaction space free of impurities and at least two different reactants (precursor or other reactant vapors) are injected in vapor phase alternately and repetitively into the reaction space. Reactant vapors can accordingly comprise a vapor that includes one or more reactants and one or more solvents. The film growth is based on alternating surface reactions that take place on the surface of the substrate to form a solid-state layer of atoms or molecules, because the reactants and the temperature of the substrate are chosen such that the alternately-injected vapor-phase reactant's molecules react only on the substrate with its surface layer. The reactants are injected in sufficiently high doses for the surface to be close to saturated during each injection cycle. Therefore, the process can be theoretically self-regulating, being not dependent on the concentration of the starting materials, whereby it is possible to achieve extremely high film uniformity and a thickness accuracy of a single atomic or molecular layer. Similar results are obtained in space-divided ALD reactors, where the substrate is moved into zones for alternate exposure to different reactants. Reactants can contribute to the growing film (precursors) and/or serve other functions, such as oxidizing, reducing or stripping ligands from an adsorbed species of a precursor to facilitate reaction or adsorption of subsequent reactants. The ALD method can be used for growing both elemental and compound thin films. ALD can involve alternate two or more reactants repeated in cycles, and different cycles can have different numbers of reactants. True ALD reactions tend to produce less than a monolayer per cycle. Practical application of ALD principles tend to have real world deviation from true saturation and monolayer limitations, and hybrid or variant process can obtain higher deposition rates while achieving some or all of the conformality and control advantages of ALD.

In some semiconductor processing devices, the solid source reactant dose can be controlled by controlling the vapor pressure in the solid source vessel, the flow rate through the solid source vessel, and the pulse time. For example, a control device such as a master flow controller (MFC) or pressure controller can be provided upstream of the solid source vessel. The control device may be remote from the heat source used to sublimate the solid reactant source due to the control device being incompatible with high temperature environments. If the sublimation rate changes, the amount of reactant delivered per pulse may vary, which can reduce wafer yields and increase costs.

Current ALD process tools do not have direct monitoring of chemical precursor dose or concentration for all chemistries, particularly for solid chemical sources which use a carrier gas. These solid sources also typically lack in-situ direct monitoring of the amount of chemical remaining in the vessel. This can result in wafer scrap due to dose fluctuations (vessel temperature variation, vessel/valve/gas line blockage or leakage) and typically requires frequent vessel changes with significant chemical remaining in the vessel to insure vessel does not become depleted during wafer processing.

Existing solutions use optical IR absorption to detect the precursor molecules. This method is expensive, and cannot be used at high temperatures. Thus, there remains a continuing demand for improved formation and delivery of reactant vapor to the reactor.

Hereafter, an apparatus and a method of the disclosed embodiments will be described in detail by way of embodiment(s) shown in the attached drawings. Unless defined otherwise, all technical and scientific terms used herein have the same meaning as is commonly understood by one skill in the art.

In the following detailed description, numerous specific details are set forth in order to provide a thorough understanding of the disclosed embodiments. However, it will be obvious to one with ordinary skill in the art that the disclosed embodiments may be practiced without these specific details. In other instances, well known methods, procedures, components, and mechanism have not been described in detail as not to unnecessarily obscure aspects of the disclosed embodiments.

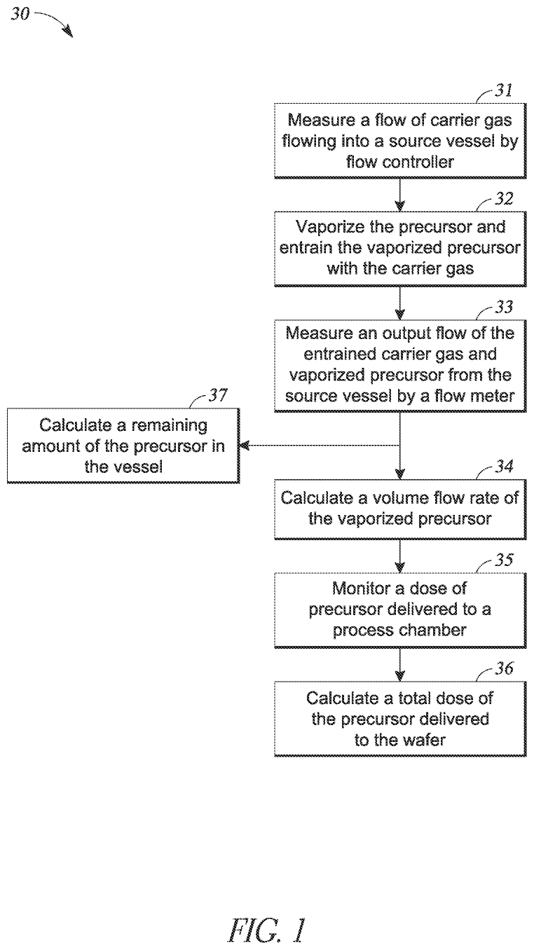

FIG. 1 is a flowchart illustrating a semiconductor processing method 30, according to various embodiments. The method 30 begins in a block 31, in which an input flow of an inactive carrier gas flowing into a source vessel is measured. The flow of the carrier gas flowing into the source vessel can be measured by a flow controller. As the flow controller, a mass-flow controller (MFC) or a pressure controller with flow monitor (PFC) can be used. An MFC may not monitor the pressure, but instead may only monitor the flow rate and have a controllable orifice that controls a fixed amount of flow. By contrast, a PFC can have a controllable orifice with a pressure gauge and can control the pressure of the carrier gas, thereby monitoring and/or controlling both pressure and flow rate. With a PFC, instead of controlling flow rate, a setpoint of pressure can be entered and the pressure at the output of the controller can be controlled. For example, an input carrier gas can have a pressure Pi at the input of the controller. To provide an output pressure Po to be lower, an orifice can be adjusted so that the output pressure stays at the setpoint value. The PFC can also measure the flow rate.

A solid or liquid precursor is disposed in the source vessel and the inactive carrier gas is provided to the source vessel. An inactive gas source can supply the inactive carrier gas to the source vessel along an inactive gas line. As the inactive carrier gas, Argon (Ar) gas or Nitrogen (N2) gas is typically used, although any other suitable inactive carrier gas can be used.

In a block 32, the precursor is vaporized through a sublimation process, for example, heated to a temperature above the sublimation temperature. The vaporized precursor can be entrained with the inactive carrier gas to deliver the vaporized precursor to the process chamber. An output flow of the entrained carrier gas and vaporized precursor from the source vessel can be measured in a block 33. The output flow from the source vessel can be measured by feeding the output flow from the source vessel to a high-temperature-compatible mass-flow meter (MFM). A MFM can be similar to an MFC, but without an adjustable orifice. Thus, MFM can monitor the flow without adjust it. In other embodiments, a MFC can be used to measure the output flow. A remaining amount of the precursor in the vessel can be calculated based on the measured input flow and the measured output flow, and in a block 37, the remaining amount of the precursor can be monitored so that an alarm can be issued when the remaining amount of the precursor is below a predetermined value.

Moving to a block 34, a volume flow rate of the vaporized precursor is calculated based on the measured input flow into the source vessel and the measured output flow therefrom. The calculation of the volume flow rate can be based on a weighted difference between the measured input flow and the measured output flow.

As set forth above, the mass-flow controller (MFC) or pressure controller with flow monitor (PFC) can control and monitor the flow of the carrier gas into the source vessel, and the high-temperature-compatible mass-flow meter (MFM) can monitor the total flow of carrier gas and precursor chemical out of the source vessel.

In general, the flow of carrier gas into the source vessel may be approximately equal to the flow out of the vessel (assuming no absorption or accumulation of gas in the vessel during steady-state operation). Thus the difference between the MFM signal and the incoming MFC/PFC signal can be proportional to the precursor flow. If the MFM is calibrated for the carrier gas (for example N2), the proportionality constant will be the ratio of the Gas Correction Factor (GCF) of the precursor chemical to the GCF of the carrier gas, and the precursor flow rate can be obtained by the below equation. GCF is dependent on gas properties and MFM measurement method.

$$Precursor flow rate = \frac{GCF Precursor gas}{GCF Carrier gas} * ( MFM readout - PFC readout )$$

Assuming that the GCF of the N₂ carrier gas is 1.0 and the MFM is calibrated for the carrier gas N₂, the above equation can be simplified as:

Precursor flow rate=GCF Precursor gas*(MFM readout−PFC readout)

This is a simple scenario in which the MFM is calibrated specifically for N₂, but it should be appreciated that with other gases the GCFs can be different. Typically, the MFM can be calibrated for N₂. It can read out a flow signal that corresponds to only N₂ flowing through it. Thus, if another carrier gas is used, a different correction (e.g., a different GCF) can be used.

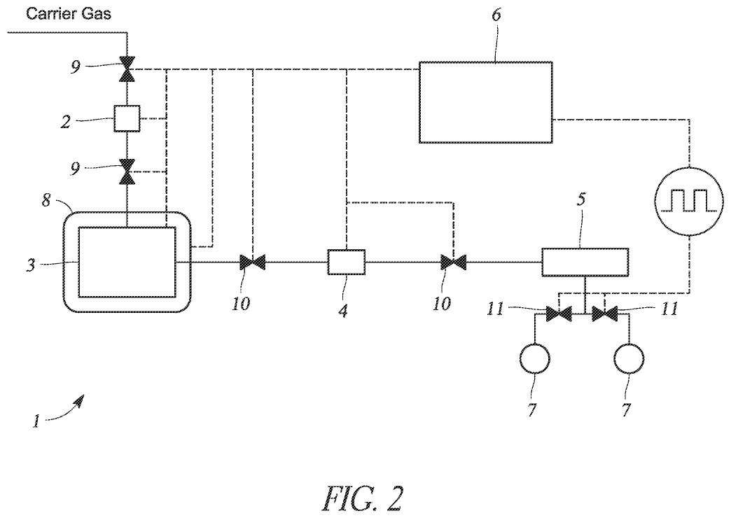

The vaporized precursor can be transferred to a process chamber 7 (see FIG. 2) and in a block 35, a dose of precursor delivered to a process chamber in which a wafer is disposed can be monitored. The process chamber can be coupled to a supply control valve which can be configured to pulse the vapored precursor to the process chamber. The dose of the precursor delivered to the process chamber can be monitored based on a signal provided to the supply control valve and the volume flow rate of the vaporized precursor. A deviation of the volume flow rate of the vaporized precursor flow can be monitored as well and an alarm can be issued, when the deviation of the volume flow rate of the vaporized precursor flow is above a predetermined value.

In block 36, a total dose of the precursor delivered to the wafer can be calculated at least based on a pulse width applied to the control valve for each process chamber and the volume flow rate of the vaporized precursor flow.

FIG. 2 is a schematic system diagram of a semiconductor processing system 1, according to various embodiments. The device 1 can comprise a source vessel 3 configured to contain a solid or liquid precursor. The source vessel 3 can include a heater 8 configured to heat the source vessel 3 to vaporize the solid or liquid precursor. A carrier gas is supplied to the source vessel 3 through a first flow measurement device 2 to entrain with the vaporized precursor to deliver the vaporized precursor to the process chamber 7. The carrier gas can be any suitable inactive gas, such as nitrogen gas or argon gas. One or more of carrier gas supply valves 9 can be provided along a gas supply line to regulate the flow of the carrier gas.

A flow of a carrier gas to the source vessel 3 can be measured by the first flow measurement device 2, which is in fluid communication with an inlet of the source vessel 3. An output flow of the entrained carrier gas and vaporized precursor from the source vessel can be measured by a second flow measurement device 4, which is in fluid communication with an outlet of the source vessel 3. One or more of entrained gas supply valves 10 can be provided downstream of the source vessel 3 to regulate the flow of the entrained gas (e.g., the entrained carrier and precursor gases). The first flow measurement device 2 can comprise a mass-flow controller (MFC) or a pressure controller with flow monitor (PFC). The second flow measurement device 4 can be a high-temperature-compatible mass-flow meter (MFM) and MFM can be calibrated for the carrier gas.

The second flow measurement device 4 can be in fluid communication with a process chamber 7 which is configured to receive one or more substrates (e.g., wafers) to be processed. A plurality of process chambers can be provided, as shown in the embodiment of FIG. 2, but it should be appreciated that, in other embodiments, the system 1 can include only a single process chamber 7. Each process chamber 7 can communicate with the second flow measurement device 4 and can be coupled to a supply control valve 11, which is configured to pulse the vapored precursor from the source vessel 3 to the process chamber 7.

A controller 6 can be provided to control an operation of the various components of the system 1. The controller 6 may comprise hardware computer processors, application-specific circuitry, and/or electronic hardware configured to execute specific and particular computer instructions to implement the process indicated in FIG. 1. The controller 6 can be configured to calculate a volume flow rate of the vaporized precursor based on the measured input flow and the measured output flow from the source vessel 3. The volume flow rate of the vaporized precursor can be calculated based on a weighted difference between the input flow into the source vessel 3 and the output flow therefrom and a dose of precursor delivered to a process chamber 7 in which a wafer is disposed can be monitored.

The controller 6 can be further configured to calculate a remaining amount of the solid or liquid precursor in the vessel 3 so that the user is aware of the amount of precursor remaining in the source vessel 3 during a deposition process. The controller 6 can be further configured to monitor a dose of precursor delivered to the process chamber 7 in which a wafer is disposed. As noted above, it can be important to accurately deliver the dose of precursor to the process chamber 7 so as to provide uniform deposition. Beneficially, the system and methods disclosed herein can enable the user to have an accurate measurement of the amount of precursor delivered to the process chamber 7 and deposited on the wafer. The controller 6 can be further configured to calculate a total dose of the precursor delivered to the wafer based at least on a pulse width applied to the supply control valve 11 for each process chamber 7 and the volume flow rate of the vaporized precursor flow. The controller 6 can be further configured to monitor a remaining amount of the precursor in the source vessel 3 and issue an alarm when the remaining amount of the precursor is below a predetermined value. The controller 6 can be further configured to monitor deviation of the volume flow rate of the vaporized precursor flow and issue an alarm an alarm when the deviation of the volume flow rate of the vaporized precursor flow is above a predetermined value.

The semiconductor processing system 1 can further comprise an accumulator 5, which is fluidly connected with the process chamber 7 and the second flow measurement device 4. The accumulator 5 can comprise a larger gas volume to accumulate precursor between pulsed supply of the vaporized precursor flow. When not using the particular precursor, the precursor can be accumulated there and can build up pressure so that a large amount of precursor is ready for the next dose.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted fairly based on the language employed in the claims and not limited to the examples described in the present specification or during the prosecution of the application, which examples are to be construed as non-exclusive.

What is claimed is:

1. A semiconductor processing system comprising:
a source vessel configured to contain a solid or liquid precursor;
a first flow measurement device in fluid communication with an inlet of the source vessel, the first flow measurement device configured to measure an input flow of a carrier gas to the source vessel;
a second flow measurement device in fluid communication with an outlet of the source vessel, the second flow measurement device configured to measure an output flow of an entrained carrier gas and vaporized precursor from the source vessel;
a process chamber in fluid communication with the second flow measurement device, the process chamber configured to receive one or more substrates; and
a controller configured to calculate a volume flow rate of the vaporized precursor based on the measured input flow and the measured output flow.

2. The semiconductor processing system according to claim 1, wherein the controller is further configured to calculate a remaining amount of the solid or liquid precursor in the vessel.

3. The semiconductor processing system according to claim 1, wherein the first flow measurement device is a mass-flow controller (MFC) or a pressure controller with flow monitor (PFC).

4. The semiconductor processing system according to claim 1 wherein the second flow measurement device is a high-temperature-compatible mass-flow meter (MFM).

5. The semiconductor processing system according to claim 4, wherein the MFM is calibrated for the carrier gas.

6. The semiconductor processing system according to claim 1, wherein the controller further configured to monitor a dose of precursor delivered to the process chamber in which a wafer is disposed.

7. The semiconductor processing system according to claim 1, wherein the process chamber is coupled to a control valve which is configured to pulse the vaporized precursor to the process chamber.

8. The semiconductor processing system according to claim 1, wherein the controller is further configured to calculate a total dose of the precursor delivered to a wafer.

9. The semiconductor processing system according to claim 8, wherein the controller is further configured to calculate a total dose of the precursor delivered to the wafer based at least on a pulse width applied to the control valve for the process chamber and the volume flow rate of the vaporized precursor flow.

10. The semiconductor processing system according to claim 1, wherein the controller is further configured to:
monitor a remaining amount of the precursor in the vessel, and
issue an alarm when the remaining amount of the precursor is below a predetermined value.

11. The semiconductor processing system according to claim 1, wherein the controller is further configured to:
monitor deviation of the volume flow rate of the vaporized precursor flow, and
issue an alarm an alarm when the deviation of the volume flow rate of the vaporized precursor flow is above a predetermined value.

12. The semiconductor processing system according to claim 1 further comprising a heater configured to heat the source vessel to vaporize the solid or liquid precursor.

13. The semiconductor processing system according to claim 1 further comprising an accumulator fluidly connected with the reaction chamber and the second flow measurement device.

14. A semiconductor processing system comprising:
a source vessel configured to contain a solid or liquid precursor;
a carrier gas source;
a first flow measurement device between the carrier gas source and the source vessel, the first flow measurement device configured to measure a measured input flow of a carrier gas from the carrier source to the source vessel;
a second flow measurement device coupled to an outlet of the source vessel, the second flow measurement device configured to measure a measured output flow of the carrier gas and a vaporized precursor from the source vessel; and
a controller configured to calculate a volume flow rate of the vaporized precursor based on the measured input flow and the measured output flow and to issue an alarm when one or more of: a remaining amount of the solid or liquid precursor is below a predetermined value or a deviation of the volume flow rate of the vaporized precursor is above a predetermined value.

15. The semiconductor processing system of claim 14, further comprising a carrier gas supply valve configured regulate a flow of the carrier gas

16. The semiconductor processing system of claim 14, further comprising one or more entrained gas supply valves downstream of the source vessel.

17. The semiconductor processing system of claim 14, wherein the controller is further configured to determine a remaining amount of the solid or liquid precursor in the source vessel.

18. The semiconductor processing system of claim 14, wherein the controller is further configured to determine a dose of the vaporized precursor

19. The semiconductor processing system of claim 14, further comprising an accumulator downstream of the source vessel.

20. A semiconductor processing system comprising:
a source vessel configured to contain a solid or liquid precursor;
a carrier gas source;
a carrier gas supply valve configured regulate a flow of the carrier gas;
a first flow measurement device between the carrier gas source and the source vessel, the first flow measurement device configured to measure a measured input flow of a carrier gas from the carrier source to the source vessel;
a second flow measurement device coupled to an outlet of the source vessel, the second flow measurement device configured to measure a measured output flow of the carrier gas and a vaporized precursor from the source vessel;
an entrained gas supply valves downstream of the source vessel; and
a controller configured to calculate a volume flow rate of the vaporized precursor based on the measured input flow and the measured output flow.
